(19) United States
(12) Patent Application Publication
(10) Pub. No.: US 2025/0203775 A1
(43) Pub. Date: Jun. 19, 2025

(54) PRINTED CIRCUIT BOARD AND MANUFACTURING METHOD FOR THE SAME

(71) Applicant: SAMSUNG ELECTRO-MECHANICS CO., LTD., Suwon-si (KR)

(72) Inventors: Sang Kee YOON, Suwon-si (KR); Yong Suk KIM, Suwon-si (KR); Kwang Su KIM, Suwon-si (KR); Joung Hun KIM, Suwon-si (KR); Tae Kyung LEE, Suwon-si (KR); Jin Uk LEE, Suwon-si (KR)

(73) Assignee: SAMSUNG ELECTRO-MECHANICS CO., LTD., Suwon-si (KR)

(21) Appl. No.: 18/894,060

(22) Filed: Sep. 24, 2024

(30) Foreign Application Priority Data
Dec. 14, 2023 (KR) 10-2023-0181532

(51) Int. Cl. H05K 1/11; H05K 1/09; H05K 3/42

(52) U.S. Cl. CPC H05K 1/115; H05K 1/09; H05K 3/425

(57) ABSTRACT

A printed circuit board and a method of manufacturing the same. The printed circuit board includes: a first insulating layer; and a plurality of first metal patterns disposed on the first insulating layer, wherein the first insulating layer has at least one recessed portion, the recessed portion is disposed between the plurality of first metal patterns, and each of the plurality of first metal patterns includes a first seed metal layer disposed on the first insulating layer, a second seed metal layer disposed on the first seed metal layer, and a metal pattern layer disposed on the second seed metal layer.

### CROSS-REFERENCE TO RELATED APPLICATION(S)

This application claims benefit of priority to Korean Patent Application No. 10-2023-0181532 filed on Dec. 14, 2023 in the Korean Intellectual Property Office, the disclosure of which is incorporated herein by reference in its entirety.

### TECHNICAL FIELD

The present disclosure relates to a printed circuit board and a manufacturing method for the same.

One of the current development directions in the semiconductor industry is to increase driving speeds by closely arranging multiple chips in a single package. In this regard, in order to overcome the fine wiring limitations of packages manufactured based on organic materials, technology has been developed to use interposers manufactured based on inorganic materials as a redistribution layer for inter-chip connections. However, in the case of interposers manufactured based on such inorganic materials, because other parts need to be formed in addition to parts required for interconnection, a process thereof may be somewhat complicated, and costs thereof may increase due to unnecessary area expansion.

### SUMMARY

An aspect of the present disclosure is to provide a printed circuit board that may form a microcircuit pattern in a required region without side effects such as undercut, and a manufacturing method for the same.

An aspect of the present disclosure is to provide a printed circuit board that may improve adhesion between insulating layers, and a manufacturing method for the same.

As one of several solutions proposed through the present disclosure, first and second seed metal layers are formed on an insulating layer, and based thereon, a metal pattern layer is formed, and then, the second seed metal layer remaining between the patterns is removed by wet etching, and the first seed metal layer is removed by dry etching to form a microcircuit pattern. Meanwhile, by such dry etching, a recessed portion may be formed in a region between the patterns of the insulating layer, and the surface roughness may be formed on a bottom surface of the recessed portion, if necessary.

For example, a printed circuit board according to an example embodiment may include: a first insulating layer; and a plurality of first metal patterns disposed on the first insulating layer, and the first insulating layer may include at least one recessed portion, the at least one recessed portion may be disposed between the plurality of first metal patterns, and each of the plurality of first metal patterns may include a first seed metal layer disposed on the first insulating layer, a second seed metal layer disposed on the first seed metal layer, and a metal pattern layer disposed on the second seed metal layer.

For example, a method of manufacturing a printed circuit board according to an example embodiment may include: forming a first seed metal layer on an insulating layer; forming a second seed metal layer on the first seed metal layer; forming a metal pattern layer on the second seed metal layer; removing at least a portion of the second seed metal layer exposed from the metal pattern layer; and removing at least a portion of the first seed metal layer exposed from the metal pattern layer and the second seed metal layer, wherein the removing of the at least the portion of the first seed metal layer includes removing at least a portion of the insulating layer to form at least one recessed portion.

One of the various effects of the present disclosure is to provide a printed circuit board that may form a microcircuit pattern in a required region without side effects such as undercuts, and a manufacturing method for the same.

Another effect of the present disclosure is to provide a printed circuit board that may improve adhesion between insulating layers and a manufacturing method of the same.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIGS. 4A to 4H are process cross-sectional views schematically illustrating an example of manufacturing the printed circuit board in FIG. 3;

FIGS. 5A, 6A, 7A, and 8A are cross-sectional images schematically illustrating a dry etching process of the first seed metal layer captured with an electron microscope, and

FIGS. 5B, 6B, 7B, and 8B are top-view images of each of the cross-sectional images;

FIG. 9 is an image captured with an electron microscope schematically illustrating an interconnection shape after dry etching of a first seed metal layer and a shape of a recessed portion formed in an insulating layer; and

FIG. 10 is a cross-sectional view schematically illustrating another example of a printed circuit board.

### DETAILED DESCRIPTION

Hereinafter, the present disclosure will be described with reference to the accompanying drawings. In the drawings, the shape and size of the elements may be exaggerated or reduced for clarity of description.

### Electronic Device

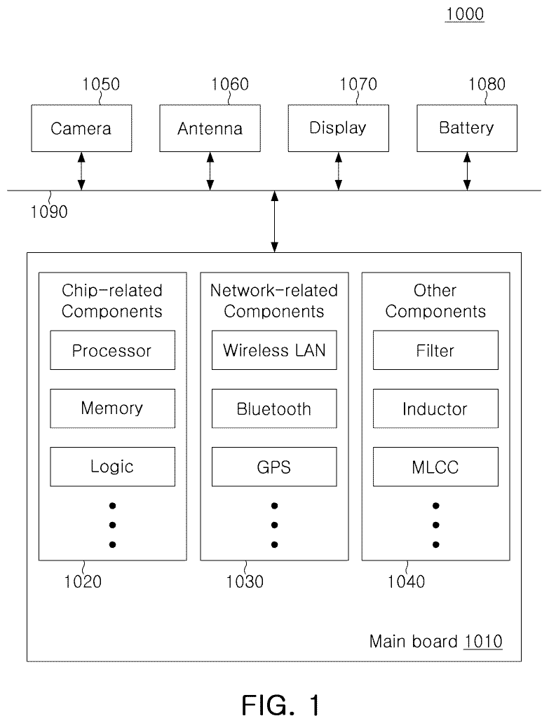

FIG. 1 is a block diagram schematically illustrating

an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may be in the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. Furthermore, these other electronic components may also other electronic components used for various purposes depending on a type of electronic device 1000.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

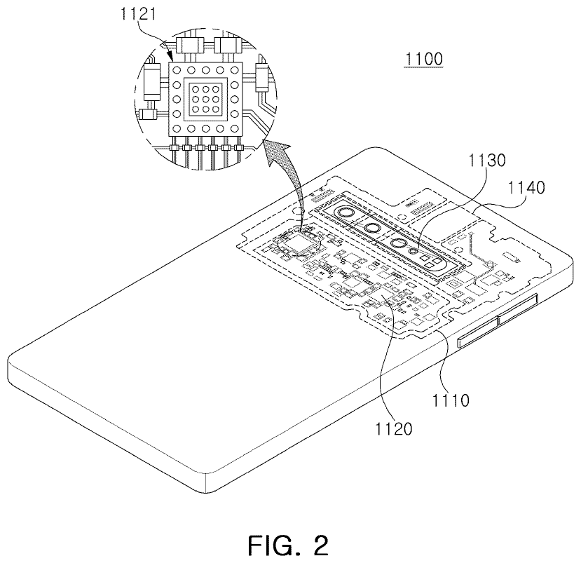

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may be in the form of a printed circuit board in which an electronic component including an active component and/or a passive component is mounted on a surface. Alternatively, the component package 1121 may be in the form of a printed circuit board in which an active component and/or a passive component are embedded. On the other hand, the electronic device is not necessarily limited to the smartphone 1100, and may be other electronic devices as described above.

### Printed Circuit Board

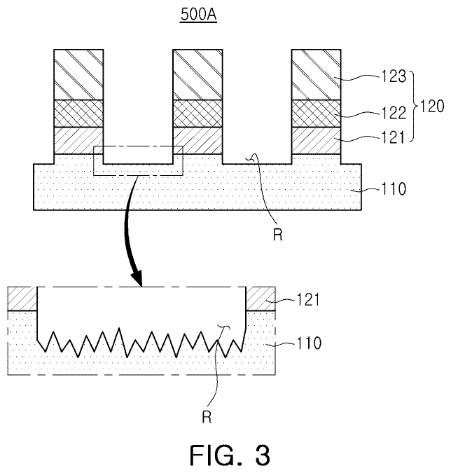

FIG. 3 is a cross-sectional view schematically illustrating an example of a printed circuit board.

Referring to FIG. 3, a printed circuit board 500A according to an example embodiment may include an insulating layer 110 and a plurality of metal patterns 120 disposed on an upper surface of the insulating layer 110. The insulating layer 110 may have at least one recessed portion R. The recessed portion R may be disposed between the plurality of metal patterns 120. Each of the plurality of metal patterns 120 may include a first seed metal layer 121 disposed on the insulating layer 110, a second seed metal layer 122 disposed on the first seed metal layer 121, and a metal pattern layer 123 disposed on the second seed metal layer 122. On the upper surface of the insulating layer 110, the metal pattern layer 123 may be thicker than each of the first seed metal layer 121 and the second seed metal layer 122.

Meanwhile, during a manufacturing process of a microcircuit board, a process for forming a multilayer microcircuit pattern may have the following order. First, titanium (Ti) and copper (Cu) may be disposed sequentially on the insulating layer as a seed metal layer. Next, copper (Cu) plating may be performed using a photoresist. Next, the photoresist may be removed, and then the seed metal layer in unnecessary positions may be sequentially removed. By repeating this process, a multilayer microcircuit pattern may be formed. In this case, wet etching may be used as a method of etching a titanium (Ti) layer, which is one of the seed metal layers, but due to the isotropic nature of the wet etching, not only etching in a longitudinal direction but also etching in a transverse direction, collectively referred to as undercut, occurs simultaneously, so that a width of the titanium (Ti) layer in an interconnection line may be narrowed. When the width of the interconnection line is wide due to design, such undercut may not be a serious problem, but in the case of microcircuit patterns, a line width of the interconnection line is significantly narrow, and thus, when the undercut occurs, the line width may be narrowed to ½ or less of the width of the interconnection line, so that the titanium (Ti) layer may be lost or may remain significantly small, resulting in peeling.

On the other hand, in the printed circuit board 500A according to an example embodiment, the first seed metal layer 121 may be removed by dry etching after performing wet etching on the second seed metal layer 122, as in a process described below. The dry etching may have anisotropic characteristics as compared to the wet etching, and thus may prevent the undercut from occurring in the first seed metal For example, even when a plurality of metal layer 121. patterns 120 include a plurality of microcircuit patterns in which L (Line)/S (Space) is 5 μm/5 μm or less, or 2 μm/2 μm or less, the above-described problem may not occur. This may prevent defective peeling of fine interconnection lines in advance, thereby improving quality defects such as shorts, opens, and signal noise that may be caused by separation of the interconnection lines. Additionally, it may be possible to provide a microcircuit board having a minimized area, thereby replacing a large-area interposer. Accordingly, costs thereof may also be saved.

On the other hand, when performing such dry etching, a recessed portion R may be formed in the insulating layer 110, in a region from which the first seed metal layer 121 is removed. For example, the recessed portion R may penetrate through a portion of the first insulating layer 110 between the plurality of metal patterns 120 in a thickness direction from the upper surface of the insulating layer 110. Accordingly, the upper surface of the insulating layer 110 in in a region in which the plurality of metal patterns 120 are disposed and the upper surface of the insulating layer 110 in a region in which the recessed portion R is disposed may have a step portion from each other. If necessary, by the dry etching, roughness may be formed on the upper surface of the insulating layer 110 in a region in which the recessed portion R is disposed. For example, the upper surface of the insulating layer 110 in the region in which the recessed portion R is disposed may have surface roughness higher than that of the upper surface of the insulating layer 110 in the region in which the plurality of metal patterns 120 are disposed. In this case, when the printed circuit board 500A is applied to a multilayer board and an additional insulating layer is formed on the insulating layer 110, a contact area between the insulating layers may be increased to improve adhesion. The surface roughness may be measured with a profilometer or laser scanner. Other methods and/or tools appreciated by one of ordinary skill in the art, even if not described in the present disclosure, may also be used.

Hereinafter, components of the printed circuit board 500A according to an example embodiment will be described in more detail with reference to the drawings.

The insulating layer 110 may include an insulating material. The insulating material may include a thermosetting resin such as an epoxy resin, a thermoplastic resin such as polyimide, or organic materials including an inorganic filler, an organic filler and/or glass fiber (Glass Fiber, Glass Cloth or Glass Fabric) along with the resin. For example, the insulating material may be a non-photosensitive insulating material such as Ajinomoto Build-up Film (ABF) or Prepreg (PPG), or a photosensitive insulating material such as Photoimageable-Dielectric (PID), but the present disclosure is not limited thereto. If necessary, the insulating material may include an inorganic material including SiO₂ and Si₃N₄.

The metal pattern 120 may include metals. Examples of the metals may include copper (Cu), aluminum (Al), silver (Ag), tin (Sn), gold (Au), nickel (Ni), lead (Pb), titanium (Ti), and/or alloys thereof. The metal pattern 120 may perform various functions depending on the design. For example, the metal pattern 120 may include a signal pattern, a power pattern, a ground patterns, or the like. The metal pattern 120 may include, preferably, the signal pattern, but the present disclosure is not limited thereto. Each of these patterns may have various forms such as lines, planes, and pads.

The first seed metal layer 121 may increase adhesion between the insulating layer 110 and the metal pattern 120. The first seed metal layer 121 may include titanium (Ti). For example, the first seed metal layer 121 may include pure titanium (pure Ti). The pure titanium (pure Ti) may denote purely including titanium (Ti) rather than alloys or oxides including titanium (Ti). For example, the first seed metal layer 121 may be formed through a deposition process such as sputtering, and thus, titanium (Ti), tantalum (Ta), nickel (Ni), chromium (Cr), and the like, may be used as the material thereof, but in consideration of the dry etching, titanium (Ti) may be, most preferably, used. However, the present disclosure is not limited thereto, and the first seed metal layer 121 may include copper (Cu), aluminum (Al), silver (Ag), tin (Sn), gold (Au), nickel (Ni), lead (Pb), titanium (Ti), and/or, alloys thereof.

The second seed metal layer 122 may provide a conductive region for electroplating (or electrolytic plating). The second seed metal layer 122 may be formed through a deposition process such as sputtering, and in consideration of adhesion to the metal pattern layer 123, conductivity, costs, and the like, the second seed metal layer 122 may include copper (Cu), for example, pure copper (Cu). The pure Cu may denote purely including copper (Cu) rather than alloys or oxides including copper (Cu). However, the present disclosure is not limited thereto, but the second seed metal layer 122 may include copper (Cu), aluminum (Al), silver (Ag), tin (Sn), gold (Au), nickel (Ni), lead (Pb), titanium (Ti), and/or alloys thereof. The second seed metal layer 122 may be thicker than the first seed metal layer 121.

The metal pattern layer 123 may substantially provide a function of the metal pattern 120. The metal pattern layer 123 may be formed through a plating process such as electroplating (electrolytic plating), and in consideration of the conductivity, costs, and the like, the metal pattern layer 123 may include copper (Cu), for example, pure copper (Cu). Meanwhile, the pure Cu may denote purely including copper (Cu) rather than alloys or oxides including copper (Cu). However, the present disclosure is not limited thereto, and the metal pattern layer 123 may include copper (Cu), aluminum (Al), silver (Ag), tin (Sn), gold (Au), nickel (Ni), lead (Pb), titanium (Ti), and/or alloys thereof. The metal pattern layer 123 may be thicker than the first and second seed metal layers 121 and 122, respectively.

A bottom surface (e.g., a fourth surface) and a wall surface (e.g., a fifth surface) of the recessed portion R may be substantially angled. As used herein, the term “substantially” may provide an industry-accepted tolerance for the corresponding terms and/or relativity between items, such as a tolerance of ±1%, ±5%, or ±10% of the actual value stated, and other suitable tolerances, unless otherwise noted. As used herein, “substantially angled” refers to the bottom surface and the wall surface together form an angle that is in a range of 30° to 150°.

For example, the recessed portion R may have a substantially constant depth. For example, the difference between the largest value and the smallest value among the measured depths may be less than 5%. For example, when surface roughness is not considered, each of the bottom surface and the wall surface of the recessed portion R may be substantially flat. For example, the wall surface of the recessed portion R may be approximately perpendicular to the bottom surface or may have an inclination close to being vertical. For example, since the recessed portion R may be formed in the process of removing a pure metal layer such as titanium (Ti) by the dry etching, the recessed portion R may have an approximately vertical shape rather than a round shape. Accordingly, the recessed portion R may have a larger area, which may be more effective in improving adhesion between the insulating layers described above. A depth of the recessed portion R may be greater than a thickness of the first seed metal layer 121. Meanwhile, the depth of the recessed portion R may vary depending on the pattern design, such as due to the loading effect (RIE lag) during Ti dry etching.

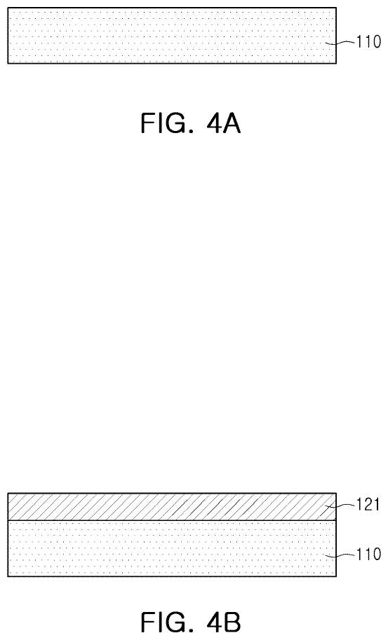

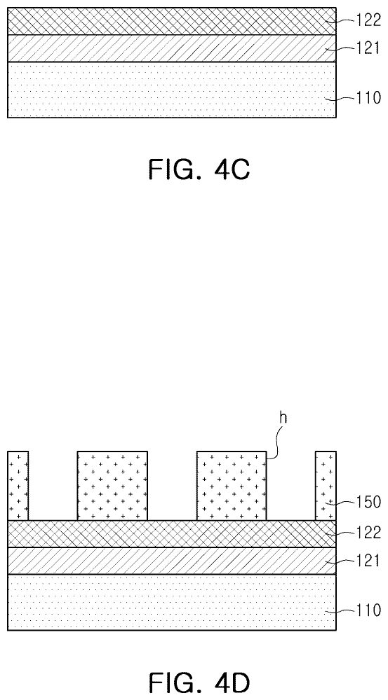

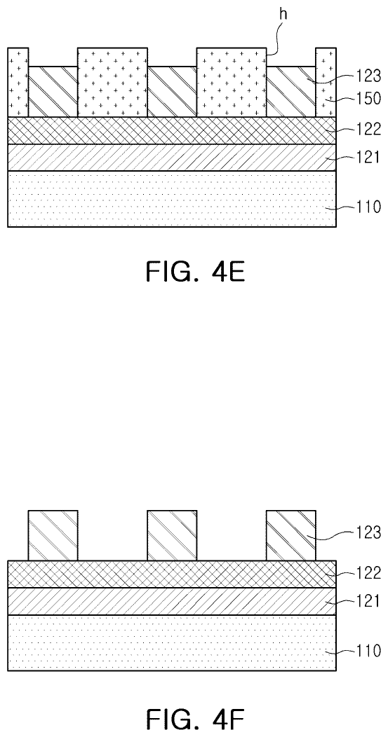

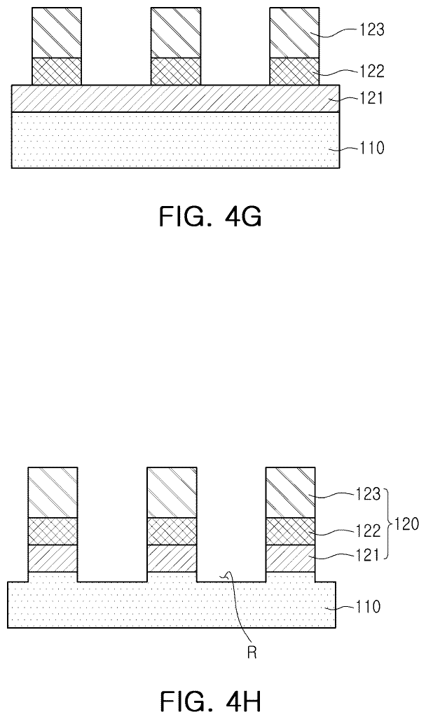

FIGS. 4A to 4H are process cross-sectional views schematically illustrating an example of manufacturing the printed circuit board in FIG. 3.

Referring to FIG. 4A, an insulating layer 110 may be prepared. The insulating layer 110 may include an organic material or an inorganic material as described above.

Referring to FIG. 4B, a first seed metal layer 121 may be formed on the insulating layer 110. As described above, the first seed metal layer 121 may be formed using a material such as titanium (Ti) in a deposition process such as sputtering.

Referring to FIG. 4C, a second seed metal layer 122 may be formed on the first seed metal layer 121. As described above, the second seed metal layer 122 may be formed using a material such as copper (Cu) in a deposition process such as sputtering.

Referring to FIG. 4D, a resist layer 150 having a plurality of openings h may be formed on the second seed metal layer 122. The resist layer 150 may include a photosensitive insulating material. The plurality of openings h may be formed in a photolithography process. Each of the plurality of openings h may expose at least a portion of the second seed metal layer 122.

Referring to FIG. 4E, a metal pattern layer 123 may be formed in each of the plurality of openings h. For example, at least a portion of each of the plurality of openings h may be filled with copper (Cu) in a plating process such as electroplating (or electrolytic plating).

Referring to FIG. 4F, the resist layer 150 may be removed. The resist layer 150 may be removed by a physical method or a chemical method. For example, a stripping liquid or the like may be used, but the present disclosure is not limited thereto.

Referring to FIG. 4G, at least a portion of the second seed metal layer 122 exposed from the metal pattern layer 123 may be removed. For example, at least a portion of an exposed second seed metal layer 122 may be removed by wet etching. Each of the exposed second seed metal layers 122 may be removed, so that at least a portion of the first seed metal layer 121 may be exposed from the second seed metal layer 122 and the metal pattern layer 123, respectively.

Referring to FIG. 4H, at least a portion of the first seed metal layer 121 exposed from the metal pattern layer 123 and the second seed metal layer 122 may be removed. For example, at least a portion of the exposed first seed metal layer 121 may be removed by dry etching. Each of the exposed first seed metal layers 121 may be removed, so that at least a portion of the insulating layer 110 may be exposed from the first and second seed metal layers 121 and 122 and the metal pattern layer 123, respectively. Meanwhile, during a dry etching process, at least a portion of the exposed insulating layer 110 may be removed to form at least one recessed portion R. If necessary, roughness may be formed on a surface of the insulating layer 110 in which the recessed portion R is formed.

Through a series of processes, the printed circuit board 500A according to an example embodiment may be manufactured. Other descriptions may be substantially the same as those described in a printed circuit board 500A according to the above-described example embodiment, and overlapping descriptions thereof will be omitted.

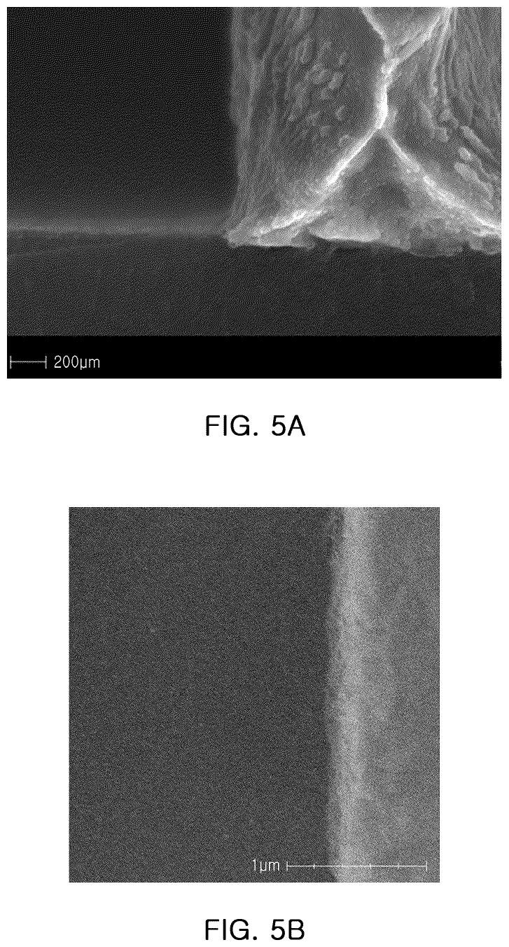

FIGS. 5A, 6A, 7A and 8A are cross-sectional images obtained captured with an electron microscope schematically illustrating the dry etching process of the first seed metal layer, and FIGS. 5B, 6B, 7B and 8B are top-view images of respective cross-sectional images.

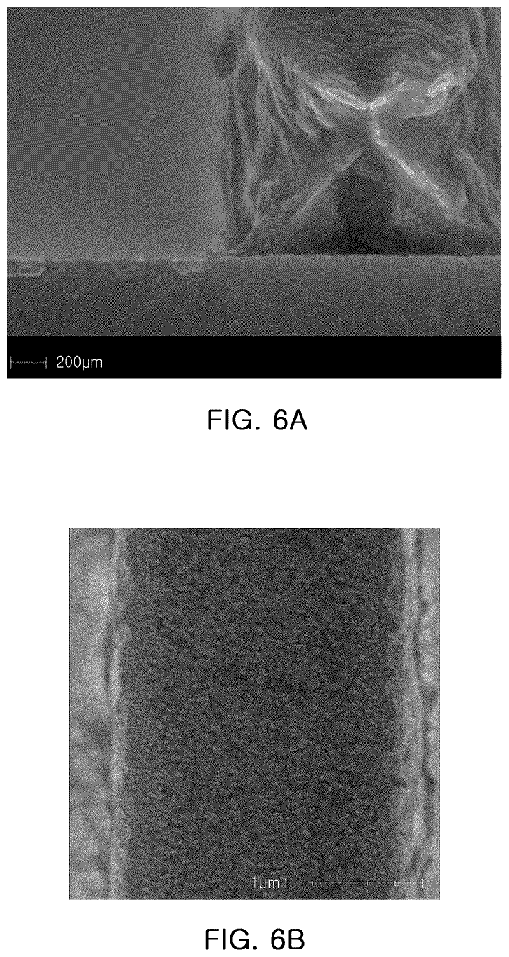

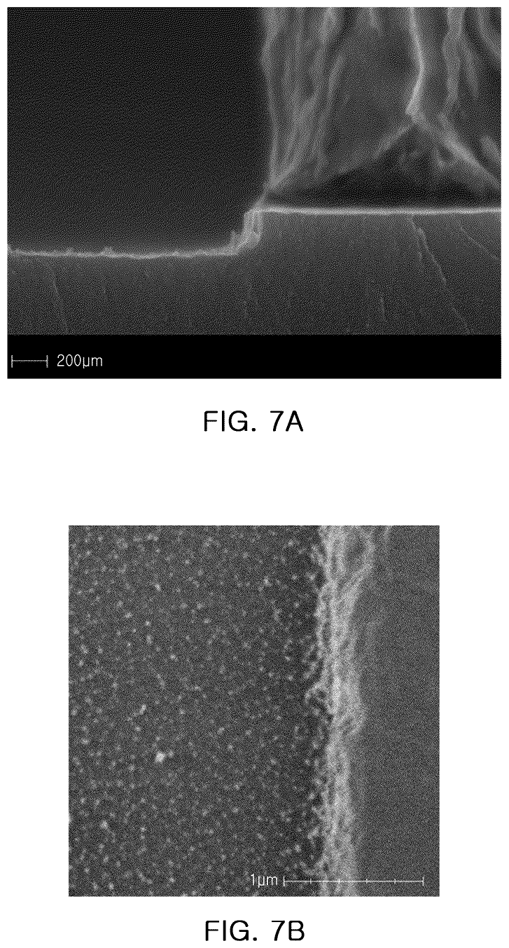

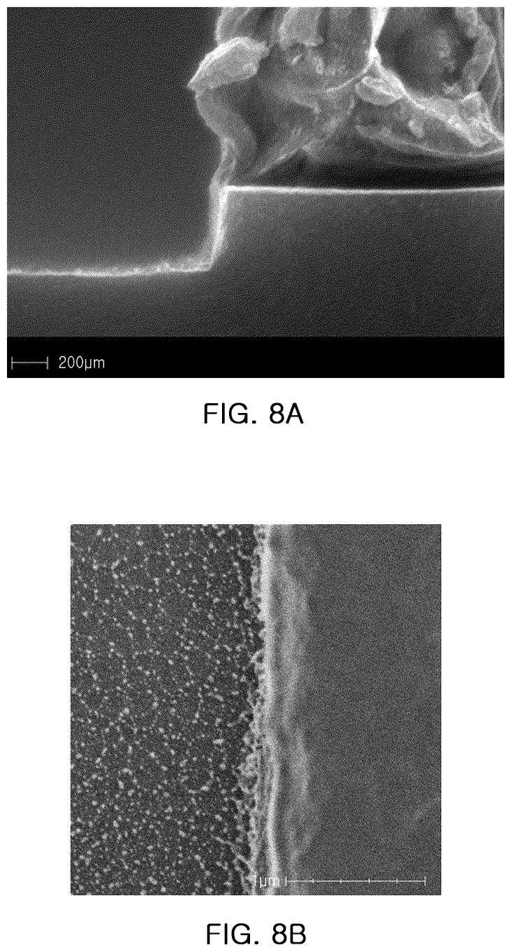

Referring to the drawing, it may be confirmed that in the dry etching of a titanium (Ti) layer having a thickness of approximately 50 nm, the insulating layer in a lower portion of the titanium (Ti) layer may maintain a shape thereof for approximately 30 to 60 seconds after etching, for example, in FIGS. 5A, 5B, 6A and 6B. On the other hand, it may be confirmed that as the etching time elapses as approximately 90 seconds and 120 seconds, the insulating layer may also be partially etched, thus forming a recessed portion including a step portion, for example, in FIGS. 7A, 7B, 8A and 8B. For example, an organic-based insulating layer may be etched by a mixed gas obtained by mixing fluorine-based gas (CF₄, CHF₃, SF₆, or the like.) or chlorine-based gas (Cl₂, BCl₃, or the like), which is etching gas for chemical reaction, in addition to etching gas for physical reaction, such as argon gas, so that an etching step portion may occur, which may also be the same for an inorganic-based insulating layer. For example, in an etching process of removing a specific material, in order to respond to a change in an etch rate due to a change in an etchant or spatial dispersion occurring in a board, additional etching time may be added to the required etching time, and in the case of the dry etching, since the etching is performed in a downward direction due to anisotropic direction, the above-described recessed portion, e.g., a recess step portion, may be formed.

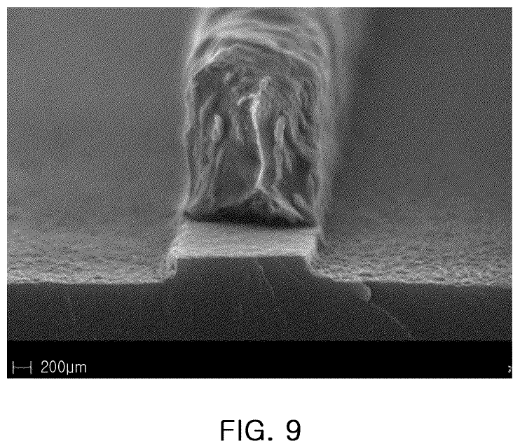

FIG. 9 is an image captured with an electron microscope schematically illustrating an interconnection shape after dry etching of a first seed metal layer and a shape of a recessed portion formed in an insulating layer.

Referring to FIG. 9, it may be seen that when removing a titanium (Ti) layer, which is a seed metal layer, by dry etching, no undercut may occur in the titanium (Ti) layer, and that the recessed portion may be formed in the insulating layer. Additionally, if necessary, it may be seen that roughness may be formed on a surface of the insulating layer in which the recessed portion is formed. Accordingly, it may be seen that sufficient width may be secured in a lower portion of the interconnection line, and the above-described technical effects may be achieved accordingly. Additionally, it may be seen that it may be possible to improve adhesion between insulating layers.

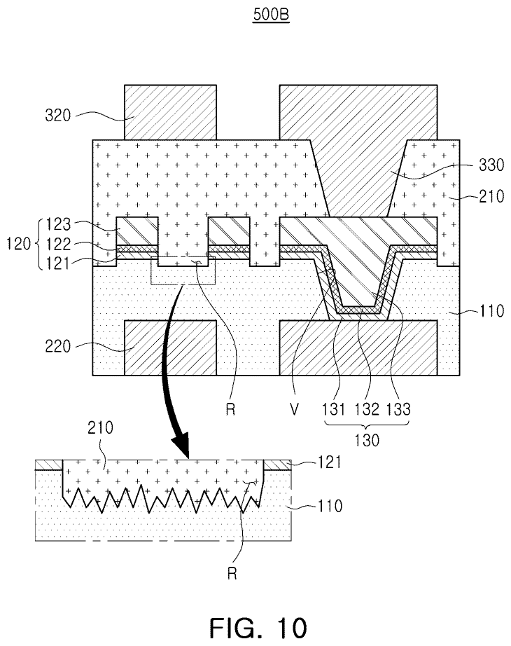

FIG. 10 is a cross-sectional view schematically illustrating another example of a printed circuit board.

Referring to FIG. 10, a printed circuit board 500B according to another example embodiment may include a first insulating layer 110, a plurality of first metal patterns 120 disposed on an upper surface of the first insulating layer 110, a plurality of second metal patterns 220 disposed below the first insulating layer 110, at least one first via pattern 130 filling at least one via hole V penetrating between an upper surface and a lower surface of the first insulating layer 110 between at least portions of each of the plurality of first and second metal patterns 120 and 220, a second insulating layer 210 disposed on an upper surface of the first insulating layer 110 and covering at least portions of each of a plurality of first metal patterns 120, a plurality of third metal patterns 320 disposed on an upper surface of the second insulating layer 210, and at least one second via pattern 330 penetrating between an upper surface and a lower surface of the second insulating layer 210 between at least portions of each of a plurality of first and third metal patterns 120 and 320.

Meanwhile, each of the plurality of first metal patterns 120 may include a first seed metal layer 121 disposed on the first insulating layer 110, a second seed metal layer 122 disposed on the first seed metal layer 121, and a first metal pattern layer 123 disposed on the second seed metal layer 122. The first via pattern 130 may include a third seed metal layer 131 disposed on a wall surface of the via hole V and at least portions of the plurality of second metal patterns 220, a fourth seed metal layer 132 disposed on the third seed metal layer 131, and a second metal pattern layer 133 disposed on the fourth seed metal layer 132 and filling at least a portion of the via hole V. The first and third seed metal layers 121 and 131 may be the same layer formed together in a deposition process or the like, and the like, and the second and fourth seed metal layers 122 and 132 may be the same layer formed together in the deposition process or the like, and the first and second metal pattern layers 123 and 133 may be the same layer formed together in a plating process or the like. For example, the same layer may include the same metal and may be integrated with each other without boundaries.

As described above, the printed circuit board 500B according to another example embodiment may be a multilayer circuit board, and may include the insulating layer 110 of the printed circuit board 500A according to the above-described example embodiment, as an internal layer, a plurality of metal patterns 120, and a recessed portion R. For example, the structure of the printed circuit board 500A according to the above-described example embodiment may be applied as an internal layer of a multilayer circuit board such as the printed circuit board 500B according to another example embodiment. However, the present disclosure is not limited to this, and the structure of the printed circuit board 500A may be applied as an external layer of the multilayer circuit board, or may be applied to both the internal layer and the external layer. On the other hand, the printed circuit board 500B according to another example embodiment may be formed with more multilayers, and may include, for example, a larger number of insulating layers, metal pattern layers, and via pattern layers. Additionally, the structure of the printed circuit board 500A according to the above-described example embodiment may be freely applied to the internal layer and the external layer depending on the design. Additionally, if necessary, the structure of the printed circuit board 500A according to the above-described example embodiment may be partially introduced only in portions requiring connection of interconnection lines. The printed circuit board 500B according to another example embodiment of the multilayer circuit board structure may be used as a Flip-Chip Board (FCB), Ball Grid Array (BGA), an interposer board, a package board, an interconnect bridge board, and the like. However, the present disclosure is not limited thereto, and the printed circuit board 500B according to another example embodiment may be applied to various other types of boards.

Hereinafter, components of the printed circuit board 500B according to another example embodiment will be described in more detail with reference to the drawings.

Each of the first and second insulating layers 110 and 210 may include an insulating material. The insulating material may include a thermosetting resin such as an epoxy resin, a thermoplastic resin such as polyimide, or organic materials including an inorganic filler, an organic filler and/or glass fiber (Glass Fiber, Glass Cloth or Glass Fabric) along with the resin. For example, the insulating material may be a non-photosensitive insulating material such as Ajinomoto Build-up Film (ABF) or Prepreg (PPG), or a photosensitive insulating material such as Photoimageable Dielectric (PID). If necessary, the insulating material may include an inorganic material including SiO₂ and Si₃N₄. The first and second insulating layers 110 and 210 may include the same insulating material, and if necessary, the first and second insulating layers 110 and 210 may be integrated with each other without boundaries. However, the present disclosure is not limited thereto, and the first and second insulating layers 110 and 210 may include different insulating materials, and may have distinct boundaries.

Each of the first to third metal patterns 120, 220 and 320 may include metals. Examples of the metals may include copper (Cu), aluminum (Al), silver (Ag), tin (Sn), gold (Au), nickel (Ni), lead (Pb), titanium (Ti), and/or alloys thereof. Each of the first to third metal patterns 120, 220 and 320 may perform various functions depending on the design. For example, the first to third metal patterns 120, 220 and 320 may include a signal pattern, a power pattern, and a ground pattern. Each of these patterns may have various forms such as lines, planes, and pads. Each of the second and third metal patterns 220 and 320 may be formed in a plating process using a Semi Additive Process (SAP), Modified SAP (MSAP), Tenting (TT) or the like, and may include, for example, an electroless plating layer and an electrolytic plating layer, but the present disclosure is not limited thereto. If necessary, the second and third metal patterns 220 and 320 may include a sputtering layer instead of an electroless plating layer, or may include both the sputtering layer and the electroless plating layer.

The plurality of first metal patterns 120 may be a finer circuit pattern than that of each of the plurality of second and third metal patterns 220 and 320. For example, a line width and a gap of line patterns among the plurality of first metal patterns 120 may be smaller than a line width and a gap of line patterns among the plurality of second metal patterns 220, and may be smaller than a line width and a gap of line patterns among the plurality of third metal patterns 320. Additionally, a pitch of a pad pattern among the plurality of first metal patterns 120 may be smaller than a pitch of a pad pattern among the plurality of second metal patterns 220, and may be smaller than a pitch of a pad pattern among the plurality of third metal patterns 320. For example, the plurality of first metal patterns 120 may include a higher density pattern than that of each of the plurality of second and third metal patterns 220 and 320.

Each of the first and second via patterns 130 and 330 may include metals. Examples of the metals may include copper (Cu), aluminum (Al), silver (Ag), tin (Sn), gold (Au), nickel (Ni), lead (Pb), titanium (Ti), and/or alloys thereof. Each of the first and second via patterns 130 and 330 may include a filled via that fills a via hole, and may include a conformal via disposed along a wall surface of the via hole. Each of the first and second via patterns 130 and 330 may perform various functions depending on the design. For example, the first and second via patterns 130 and 330 may include a ground via, a power via, and a signal via. Each of the first and second via patterns 130 and 330 may have a shape tapered in the same direction in cross-section. For example, a width of an upper end thereof may be greater than a width of a lower end thereof in each cross-section. The second via pattern 330 may be formed in a plating process using a Semi Additive Process (SAP), Modified SAP (MSAP), Tenting (TT), or the like, and may include, for example, an electroless plating layer and an electrolytic plating layer, but the present disclosure is not limited thereto, and the first and second via patterns 130 and 330 may include the sputtered layer instead of the electroless plating layer, or may include both the sputtered layer and the electroless plating layer.

Each of the first and third seed metal layers 121 and 131 may increase adhesion between the first insulating layer 110 and the first metal pattern 120 and between the first insulating layer 110 and the first via pattern 130, respectively. The first and third seed metal layers 121 and 131 may include the same metal, for example, titanium (Ti). For example, the first and third seed metal layers 121 and 131 may include pure titanium (pure Ti). The pure titanium (pure Ti) may denote purely including titanium (Ti) rather than alloys or oxides including titanium (Ti). For example, the first and third seed metal layers 121 and 131 may be formed together in a deposition process such as sputtering, and titanium (Ti), tantalum (Ta), nickel (Ni), chromium (Cr), and the like, may be used as materials thereof, but in consideration of dry etching, titanium (Ti) may be, most preferably, used. However, the present disclosure is not limited thereto, but the first and third seed metal layers 121 and 131 may include copper (Cu), aluminum (Al), silver (Ag), tin (Sn), gold (Au), nickel (Ni), lead (Pb), titanium (Ti), and/or alloys thereof.

The second and fourth seed metal layers 122 and 132 may provide a conductive region for electroplating (or electrolytic plating). The second and fourth seed metal layers 122 and 132 may be formed together in a deposition process such as sputtering, and in consideration of the adhesion with the same metal, such as the first and second metal pattern layers 123 and 133, conductivity, costs, and the like, the second and fourth seed metal layers 122 and 132 may include copper (Cu). For example, the second and fourth seed metal layers 122 and 132 may include pure copper (Cu). The pure Cu may denote purely including copper (Cu) rather than alloys or oxides including copper (Cu). However, the present disclosure is not limited thereto, and the second and fourth seed metal layers 122 and 132 may include copper (Cu), aluminum (Al), silver (Ag), tin (Sn), gold (Au), nickel (Ni), lead (Pb), titanium (Ti), and/or alloys thereof. A thickness of the second seed metal layer 122 may be thicker than the thickness of the first seed metal layer 121.

The first and second metal pattern layers 123 and 133 may substantially provide functions of the first metal pattern 120 and the first via pattern 130. The first and second metal pattern layers 123 and 33 may be formed together in a plating process such as electroplating (electrolytic plating), and may include the same metal, for example, copper (Cu), in consideration of conductivity, costs, and the like. For example, the first and second metal pattern layers 123 and 133 may include pure copper (Cu). Meanwhile, the pure Cu may denote purely including copper (Cu) rather than alloys or oxides including copper (Cu). However, the present disclosure is not limited thereto, and the first and second metal pattern layers 123 and 133 may include copper (Cu), aluminum (Al), silver (Ag), tin (Sn), gold (Au), nickel (Ni), lead (Pb), titanium (Ti), and/or alloys thereof. A thickness of the first metal pattern layer 123 may be thicker than thicknesses of each of the first and second seed metal layers 121 and 122.

A bottom surface and a wall surface of the recessed portion R may be substantially angled. For example, the recessed portion R may have a substantially constant depth. For example, each of the bottom surface and the wall surface of the recessed portion R may be substantially flat when surface roughness is not taken into account. For example, the wall surface of the recessed portion R may be approximately perpendicular to the bottom surface or may have an inclination close to being vertical. For example, because the recessed portion R may be formed in a process of removing a pure metal layer such as titanium (Ti) by dry etching, the recessed portion R may have an approximately vertical shape rather than a round shape or the like, so that the recessed portion R may have a larger area, thereby effectively improving adhesion between the first and second insulating layers 110 and 210. A depth of the recessed portion R may be greater than the thickness of the first seed metal layer 121.

The via hole V may be formed in the first insulating layer 110 before forming the first seed metal layer 121. For example, depending on the material of the first insulating layer 110, the via hole V may be formed using various methods as such mechanical drilling, laser The via hole V may be processing, or chemical etching. formed to penetrate through the first insulating layer 110. When forming the first seed metal layer 121 after forming the via hole V, a third seed metal layer 131 may be formed in the via hole V. Additionally, when forming the second seed metal layer 122, a fourth seed metal layer 132 may be formed in the via hole V. Additionally, when forming the first metal pattern layer 123, a second metal pattern layer 133 may be formed within the via hole V.

Since other descriptions may be substantially the same as those described in a manufacturing example of the printed circuit board 500A according to the above-described example embodiment and the printed circuit board 500A according to an example embodiment, overlapping descriptions thereof will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partial filling, or may include a case of approximately filling. For example, the expression ‘filling’ may include a case in which some pores or voids exist. Furthermore, the expression ‘surrounding’ may include not only a case of completely surrounding but also a case of at least partial surrounding, or may include a case of approximately surrounding. Additionally, the expression ‘adjacent’ refers to a case in which elements are disposed next to each other on substantially the same layer, and is not limited to cases in which elements are in contact with each other. Additionally, exposure may include not only complete exposure but also partial exposure, and the exposure may denote exposure from burying a corresponding element.

In the present disclosure, substantially, determination may be performed by including a process error or a positional deviation occurring in a manufacturing process, and an error during measurement. For example, being substantially coplanar may include not only a case in which components exist on the completely same plane, but also a case in which components exist on approximately the same plane.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, an angle, an L (Line)/S (Space), and the like, may be measured using a scanning microscope or an optical microscope based on a cross-section obtained by polishing or cutting a printed circuit board. Other methods and/or tools appreciated by one of ordinary skill in the art, even if not described in the present disclosure, may also be used. A cut cross-section may be a vertical cross-section or a horizontal cross-section, and respective values thereof may be measured based on the required cut cross-section. For example, a width of an upper portion and/or a lower portion of a via may be measured on a cross-section cut along a central axis of the via. In this case, when values are not constant, the value may be determined as a value obtained by averaging values measured at five random points. Meanwhile, a minimum value may be determined as the smallest value measured on the corresponding layer or region.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a first insulating layer; and
a plurality of first metal patterns disposed on the first insulating layer,
wherein the first insulating layer includes at least one recessed portion,
the at least one recessed portion is disposed between the plurality of first metal patterns, and
each of the plurality of first metal patterns includes a first seed metal layer disposed on the first insulating layer, a second seed metal layer disposed on the first seed metal layer, and a metal pattern layer disposed on the second seed metal layer.

2. The printed circuit board according to claim 1,
wherein the first seed metal layer includes titanium (Ti),
the second seed metal layer includes copper (Cu), and the metal pattern layer includes copper (Cu).

3. The printed circuit board according to claim 1,
wherein the plurality of first metal patterns are disposed on a first surface of the first insulating layer, and
the metal pattern layer is thicker than each of the first and second seed metal layers.

4. The printed circuit board according to claim 3,
wherein the first insulating layer includes a step portion between the first surface of the first insulating layer in a first region in which the plurality of first metal patterns are disposed and the first surface of the first insulating layer in a second region in which the at least one recessed portion is disposed.

5. The printed circuit board according to claim 3,
wherein the first surface of the first insulating layer in a region in which the at least one recessed portion is disposed has a surface roughness higher than that of the first surface of the first insulating layer in a region in which the plurality of first metal patterns are disposed.

6. The printed circuit board according to claim 3,
wherein the at least one recessed portion penetrates through a portion of the first insulating layer in a thickness direction from the first surface of the first insulating layer between the plurality of first metal patterns.

7. The printed circuit board according to claim 3, further comprising:
a plurality of second metal patterns disposed on a second surface of the first insulating layer;
at least one via pattern filling at least one via hole penetrating a first region of the first insulating layer between the first surface and the second surface of the first insulating layer, wherein the first region of the first insulating layer is between at least some portions of each of the plurality of first and second metal patterns,
wherein the at least one via pattern includes:
the first seed metal layer disposed on a wall surface of the via hole and at least a portion of the plurality of second metal patterns,
the second seed metal layer disposed on the first seed metal layer, and
the metal pattern layer disposed on the second seed metal layer and filling at least a portion of the via hole.

8. The printed circuit board according to claim 7, wherein a first portion of the plurality of second metal patterns directly contacts the first seed metal layer.

9. The printed circuit board according to claim 8, wherein the first portion overlaps the first see metal layer, the second seed metal layer, and the metal pattern layer, in order.

10. The printed circuit board according to claim 7, wherein a second portion of the plurality of second metal patterns overlaps adjacent first metal patterns among the plurality of first metal patterns.

11. The printed circuit board according to claim 3, further comprising:
a second insulating layer disposed on the first surface of the first insulating layer and covering at least a portion of each of the plurality of first metal patterns; and
a plurality of third metal patterns disposed on a third surface of the second insulating layer.

12. The printed circuit board according to claim 1, wherein the at least one recessed portion has a fourth surface and a fifth surface that are substantially angled with each other.

13. The printed circuit board according to claim 12, wherein the at least one recessed portion has a substantially constant depth.

14. The printed circuit board according to claim 1, wherein the plurality of first metal patterns includes a plurality of microcircuit patterns having an L (Line)/S (Space) that is 5 μm/5 μm or less.

15. A method of manufacturing a printed circuit board, comprising:
forming a first seed metal layer on an insulating layer;
forming a second seed metal layer on the first seed metal layer;
forming a metal pattern layer on the second seed metal layer;
removing at least a portion of the second seed metal layer exposed from the metal pattern layer; and
removing at least a portion of the first seed metal layer exposed from the metal pattern layer and the second seed metal layer,
wherein the removing of the at least the portion of the first seed metal layer includes removing at least a portion of the insulating layer to form at least one recessed portion.

16. The method of manufacturing a printed circuit board according to claim 15,
wherein the forming of the first seed metal layer includes depositing titanium (Ti) to form the first seed metal layer,
the forming of the second seed metal layer includes depositing copper (Cu) to form the second seed metal layer, and
the forming of the metal pattern layer includes forming a resist layer having a plurality of openings on the second seed metal layer, then filling the plurality of openings with copper (Cu) by plating, and then removing the resist layer to form the metal pattern layer.

17. The method of manufacturing a printed circuit board according to claim 15,
wherein in the removing of the at least the portion of the second seed metal layer, the at least the portion of the second seed metal layer is removed by wet etching,
in the removing of the at least the portion of the first seed metal layer, the at least the portion of the first seed metal layer is removed by dry etching, and
the at least one recessed portion is formed by the dry etching.

18. The method of manufacturing a printed circuit board according to claim 15,
wherein in the removing of the at least the portion of the first seed metal layer, a surface of the insulating layer in a region in which the at least one recessed portion is formed has a higher surface roughness than that of a surface of the insulating layer in a region in which the metal pattern layer is formed.

19. The method of manufacturing a printed circuit board according to claim 15, further comprising, before the forming of the first seed metal layer, forming a via hole penetrating through the insulating layer,
wherein the forming of the first seed metal layer, the forming of the second seed metal layer, and the forming of the metal pattern layer includes forming at least a portion of the first seed metal layer, at least a portion of the second seed metal layer, and at least a portion of the metal pattern layer, respectively, in the via hole.
